(19) United States
(12) Patent Application Publication
(10) Pub. No.: US 2006/0073286 A1
(43) Pub. Date: Apr. 6, 2006

(54) Skirting board structure

(76) Inventor: Hsun-Chuan Chuang, Jhonghe City (TW)

Correspondence Address: Troxell Law Office Pllc, Suite 1404, 5205 Leesburg Pike, Falls Church, VA, 22041, US

(21) Appl. No.: 11/224,933

(22) Filed: Sep. 14, 2005

(30) Foreign Application Priority Data
Oct. 4, 2004 (TW) 093215692

(51) Int. Cl. G03F 1/14

(52) U.S. Cl. 428/14

(57) ABSTRACT

A skirting board structure is primarily composed of a positioning board and a decorative board. The positioning board is in form of a thin sheet, the top of which is provided with a gap such that the adjacent side of the gap will form an engagement flake. The positioning board can be firmly fastened to the bottom of a wall. The decorative board has a slot between a long side and a short side, such that after the positioning board is fastened to the wall bottom, the decorative board can be combined with the positioning board by way of engaging the slot with the engagement flake of the positioning board.

### BACKGROUND OF THE INVENTION

(a) Field of the Invention

The present invention relates to a skirting board structure, which, being easily and economically manufactured, as well as instantly and conveniently constructed and assembly, is particularly suitable to DIY (Do It Yourself) by oneself to complete the interior decoration. As the skirting board of the invention can be freely assembled to decorate the wall bottom, it is applicable to dwelling houses and offices.

(b) Description of the Prior Art

R.O.C. Patent No. 456407 disclosed a “Skirting board having spaced panels” which is composed of a positioning element, being in form of a U cross-section, i.e. having a groove in the middle, with one side thereof adhered to the wall bottom. A combination board is also provided, the two sides of which are provided with a pair of outwardly extending relief boards. Wherein one of the relief boards can be inserted into the groove of the positioning element. A panel is further provided with a reverse L shape card board inwardly and horizontally extending at the panel top, and a n-shape locking board formed at the panel bottom for inserting downwardly into the positioning element.

As the aforementioned prior art has a positioning element of U cross-section, it can hardly maintain a vertical flexibility. As such, when the positioning element is fixed to the wall by nails, it cannot be closely adhered to the concrete wall. Besides, after the relief board is inserted into the groove of the positioning element, and then the panel is further inserted onto the positioning element with the n-shape locking board engaged with the U-shape groove, the groove is easily exposed due to the uneven status of the concrete floor. The greatest disadvantage existing in the prior art is that it is not adjustable.

Accordingly, there exists a need for a simple skirting board structure, which can reduce the manufacture cost, and is fast constructed, as disclosed in the present invention.

### SUMMARY OF THE INVENTION

The primary object of the invention is to provide a skirting board, which is neat, easily assembled, and freely applicable to the wall bottom of dwelling houses and offices, and therefore efficiently enhancing the artistic feeling of environments.

The secondary object of the invention is provide a skirting board which can improve the quality of constructions, and is particularly suitable to personal DIY that does not require professional skill.

To obtain the above objects, the skirting board of the invention is primarily composed of a positioning board and a decorative board. The top of the positioning board is provided with a gap and an engagement flake, while the decorative board has a slot between a long side and a short side, such that after the positioning board is pre-fastened to the wall bottom, the decorative board can be engaged with the engagement flake of the positioning board from top to the bottom, thereby the decorative board will cover the positioning board to present an artistic appearance.

To completely appreciate these and other objects of the present invention as well as the invention itself, all of which will become apparent to those skilled in the art, the following detailed description of the invention and the claims should be read in conjunction with the accompanying drawings.

### BRIEF DESCRIPTION OF THE DRAWINGS

FIG. 1 is a perspective view of the present invention.

FIG. 2 is an exploded view of present invention.

FIG. 3 is a cut-away view showing the present invention in a combination status.

FIG. 4 is a cut-away view of the components of the present invention.

FIG. 5 shows an embodiment of the present invention.

FIG. 6 shows application of the present invention.

### DETAILED DESCRIPTION OF THE PREFERRED EMBODIMENTS

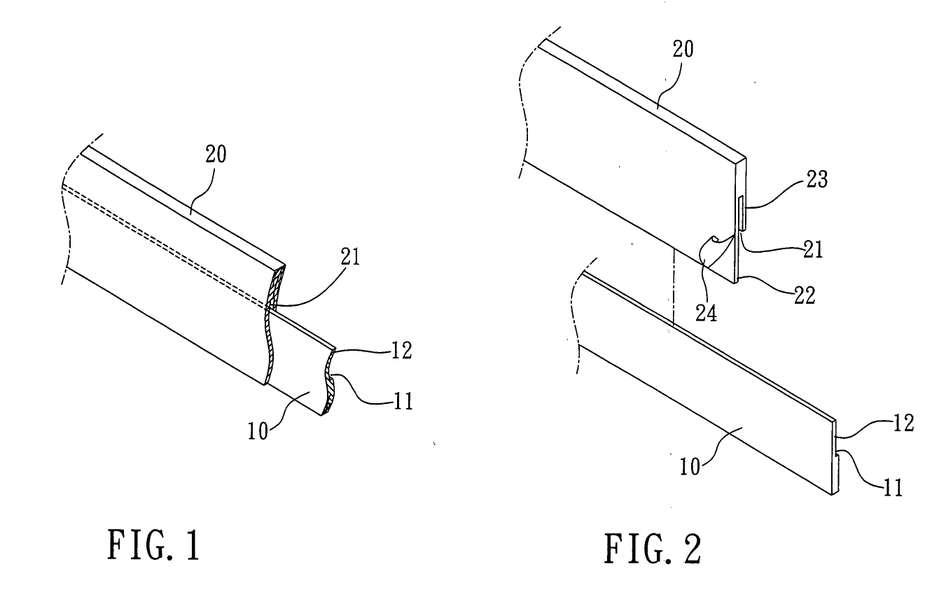

As shown in FIGS. 1 and 2, the present invention relates to a skirting board structure, which is primarily composed of a positioning board 10 and a decorative board 20 combined With the position board 10. The invention is characterized in that:

The positioning board 10, being in form of a long and thin sheet, which is provided with a gap 11, thereby forming an engagement flake 12 at the adjacent edge. While the position board 10 in its entirety is in form of a long and thin sheet, it is vertically flexible and therefore can be closely adhered to the concrete wall which is not necessarily plane.

The decorative board 20 is also in form of a long and thin sheet, which has a slot 21 between a front long side 22 and a rear short side 23. The width of the slot 21 is at least greater than or identical with the thickness of the engagement flake 12, such that the slot 21 can engage with the engagement flake 12 of the position board 10 for combination purposes. The surface of the decorative board can be provided with a removable laminate 24 which can be torn off after completing the painting work for the interior walls, thereby keeping clean.

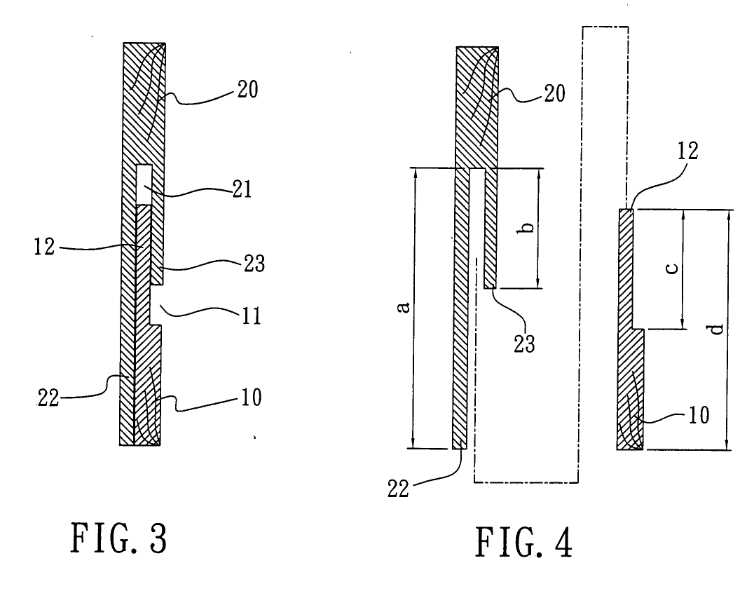

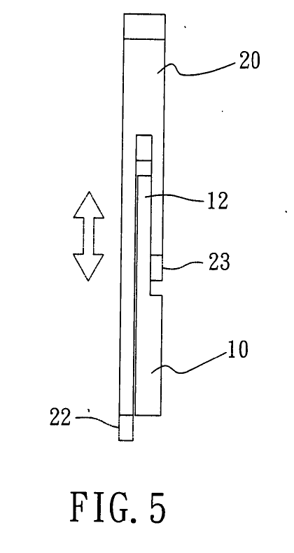

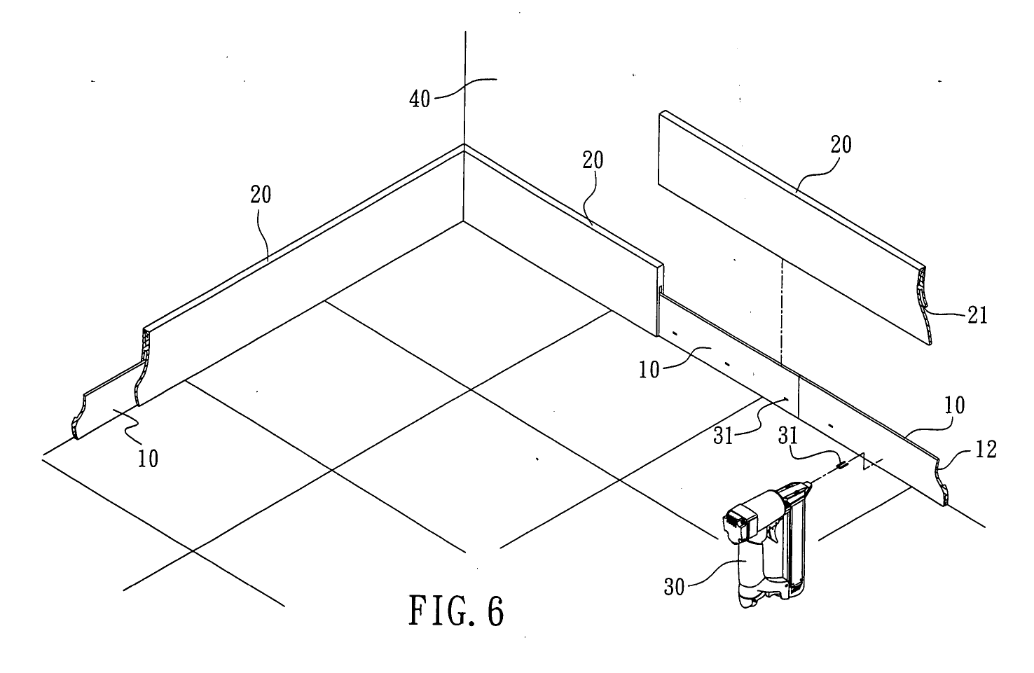

Referring to FIGS. 3 and 4, based on the composing elements, i.e. position board 10 and the decorative board 20 as mentioned above, in order to obtain a flawless use status of the invention, the long side 22 of the decorative board 20 may have a length a, while the short side 23 may have a length b, whereas the engagement flake 12 (i.e. gap 11) of the position board 10 may have a length c, and the position board 10 may be set with a height d. The length a of the long side 22 is greater than or identical with the length d of the positioning board 10, such that the decorative board 20 can completely cover the position board 10. Besides, the length b of the short side 23 must not be greater than the length c of the gap 11, such that the decorative board 20 can slide down to the bottom of the positioning board 10 to completely cover the positioning board 10 (as shown in FIG. 5). Referring to FIGS. 4 to 6, accordingly, after the positioning board 10 is prefixed to the wall 40 bottom via pneumatic stapler 30 and staples 31, the decorative board 20 can be engaged with the positioning board 10 by way of engaging the slot 21 with the engagement flake 12, thereby accomplishing a perfect skirting board structure, which presents an artistic appearance due to the fine and smooth joint.

As the positioning board 10 is generally made of a low-priced board, and fixed to the wall 40 bottom via nails 31, after the decorative board 20 mounted on the positioning board 10 can hide the nails 31 and enhance the quality of the work without showing the mark or stain occurred during processing. Furthermore, the skirting board can remain an artistic outer appearance despite the nails 31 become rusty after a period of time.

Accordingly, the present invention has the following advantages:

1. As the positioning board and the decorative board are directly engaged with each other from top and down, the operation is easy and the invention is particularly applicable to the uneven floor by simply remove the decorative board upwardly or downwardly.

2. The decorative board can be provided with various patterns. As such, the decorative board can be firmly engaged with the positioning board under a fast assembly and an easy construction. Meanwhile, it is practical and convenient to alter the interior decoration as desired by way of DIY.

Although specific embodiments have been illustrated and described, it will be obvious to those skilled in the art that various modifications may be made without departing from what is intended to be limited solely by the appended claims.

Concluded above, the invention not only can improve the disadvantages existing in the prior arts, but also can accomplish a convenient and fast assembly, and reduce the cost, thereby greatly enhancing the integral practicality and convenience. The invention is particularly applicable to decoration and embellishment of wall bottom, thus the utility is undoubtedly.

What is claimed is:

1. A skirting board structure, comprising a positioning board and a decorative board, wherein,
the positioning board is in form of a thin sheet, which is provided with a gap to form an engagement flake; the decorative board is also in form of a thin sheet, which has a slot between a long side and a short side, such that the decorative board can combine with the positioning board by way of engaging the slot with the engagement flake of the positioning board.

2. The skirting board according to claim 1, wherein the short side of the decorative board has a height not greater than that of the gap on the positioning board.

3. The skirting board according to claim 1, wherein the long side of the decorative board has a height not smaller than that of the positioning board.

4. The skirting board according to claim 1, wherein the thickness of the engagement flake of the positioning board is not greater than the width of the slot of the decorative board.

5. The skirting board according to claim 1, wherein the surface of the decorative board is provided with a removable laminate.
